(19) United States
(12) Patent Application Publication
(10) Pub. No.: US 2021/0013701 A1
(43) Pub. Date: Jan. 14, 2021

(54) QUANTUM CASCADE LASER

(71) Applicant: SUMITOMO ELECTRIC INDUSTRIES, LTD., Osaka (JP)

(72) Inventors: Jun-ichi HASHIMOTO, Osaka-shi (JP); Hiroyuki YOSHINAGA, Osaka-shi (JP)

(73) Assignee: SUMITOMO ELECTRIC INDUSTRIES, LTD., Osaka (JP)

(21) Appl. No.: 16/906,079

(22) Filed: Jun. 19, 2020

(30) Foreign Application Priority Data
Jul. 9, 2019 (JP) 2019-127526

(51) Int. Cl. H01S 5/34; H01S 5/227; H01S 5/042; H01S 5/026; H01S 5/12

(52) U.S. Cl. CPC H01S 5/3402; H01S 5/227; H01S 5/1203; H01S 5/026; H01S 5/0425

(57) ABSTRACT

A quantum cascade laser includes a laser structure including a semiconductor stack and a semiconductor support, the laser structure having a first end face and a second end face opposite the first end face. The semiconductor stack is disposed on the semiconductor support. The laser structure includes a semiconductor mesa and a buried region, the semiconductor mesa including a core layer, and the buried region embedding the semiconductor mesa. The laser structure includes a first region, a second region, and a third region. The third region is provided between the first region and the second region. The first region includes the first end face. The semiconductor mesa includes a first stripe portion, a second stripe portion, and a first tapered portion, respectively, in the first region, the second region, and the third region. The first stripe portion and the second stripe portion have different mesa widths.

### CROSS REFERENCE TO RELATED APPLICATIONS

The present application is based upon and claims the benefit of the priority from Japanese patent application No. 2019-127526, filed on Jul. 9, 2019, which is hereby incorporated by reference in its entirety.

### TECHNICAL FIELD

The present disclosure relates to a quantum cascade laser.

### BACKGROUND

Non-Patent Document 1 discloses a quantum cascade semiconductor laser.

Non-Patent Document 1: Thierry Aellen et al., APPLIED PHYSICS LETTERS, vol. 83, pp. 1929-1931, 2003

### SUMMARY

The present disclosure provides a quantum cascade laser including a laser structure including a semiconductor stack and a semiconductor support, the laser structure having a first end face and a second end face opposite to the first end face. The semiconductor stack is disposed on the semiconductor support. The laser structure includes a semiconductor mesa and a buried region, the semiconductor mesa having a core layer, and the buried region embedding the semiconductor mesa. The laser structure includes a first region, a second region, and a third region. The third region is provided between the first region and the second region. The first region includes the first end face. The semiconductor mesa includes a first stripe portion, a second stripe portion, and a first tapered portion in the first region, the second region, and the third region, respectively. The first stripe portion and the second stripe portion have different mesa widths.

### BRIEF DESCRIPTION OF THE DRAWINGS

The above and other objects, features and advantages will become more apparent from the following detailed description of the preferred embodiments with reference to the accompanying drawings.

FIG. 1A is a plan view schematically showing a quantum cascade laser according to a specific example.

FIG. 1B shows a cross-section taken along Ib-Ib shown in FIG. 1A.

FIG. 2A is a view showing a cross-section taken along IIa-IIa line shown in FIG. 1A.

FIG. 2B is a view showing a cross-section taken along IIb-IIb line shown in FIG. 1A.

FIG. 2C is a view showing a cross-section taken along IIc-IIc line shown in FIG. 1A.

FIG. 3A is a diagram showing a cross section taken along the waveguide axis.

FIG. 3B is a view showing a cross section along IIIb-IIIb line shown in FIG. 3A.

FIG. 3C is a view showing a cross section along IIIc-IIIc line shown in FIG. 3A.

FIG. 4 schematically illustrates the main steps in a method of making a quantum cascade laser according to an embodiment.

FIG. 5 schematically illustrates the main steps in a method of making a quantum cascade laser according to an embodiment.

FIG. 6 is a drawing schematically showing main steps in a method of fabricating a quantum cascade laser according to an embodiment.

FIG. 7 schematically illustrates the main steps in a method of making a quantum cascade laser according to an embodiment.

FIG. 8 schematically illustrates the main steps in a method of making a quantum cascade laser according to an embodiment.

FIG. 9 schematically illustrates a cleavage step in a method of fabricating a quantum cascade laser that fabricates a product having a structural that directly connects tapered portions in adjacent device compartments.

FIG. 10A is a diagram showing the profile of the near-field image of the quantum cascade laser (NFP).

FIG. 10B is a diagram showing the profile of the near-field image of the quantum cascade laser (NFP).

FIG. 10C is a diagram showing the profile of the far-field image of the quantum cascade laser (FFP).

FIG. 10D is a diagram showing the profile of the far-field image of the quantum cascade laser (FFP).

FIG. 11A is a plan view schematically showing a quantum cascade laser according to a specific embodiment.

FIG. 11B is a view showing a cross section taken along XIb-XIb line shown in FIG. 11A.

FIG. 12A is a plan view schematically showing a quantum cascade laser according to a specific example.

FIG. 12B is a view showing a cross section taken along XIIb-XIIb line shown in FIG. 12A.

FIG. 13A is a plan view schematically showing a quantum cascade laser according to a specific example.

FIG. 13B is a cross-sectional view taken along XIIIb-XIIIb line shown in FIG. 13A.

### DETAILED DESCRIPTION

### Problem to be Solved by the Present Disclosure

A quantum-cascade laser including III-V compound semiconductors produces a mid-infrared laser beam. The quantum cascade semiconductor laser has a front end face and a rear end face, and these end faces are formed by cleavage.

A substrate product for the quantum cascade semiconductor laser is cleaved along a cleavage line to fabricate a laser bar having a cleavage plane. According to the inventors' findings, the cleavage face may be shifted to both the left and right sides of the cleavage line.

One aspect of the present disclosure is to provide a quantum cascade laser capable of reducing an influence of positional deviations of the cleavage face with respect to the cleavage line.

### Description of Embodiments of the Present Disclosure

Several specific examples are described.

A quantum cascade laser according to a specific example includes a laser structure including a semiconductor stack and a semiconductor support, the laser structure having a first end face and a second end face opposite to the first end face. The semiconductor stack is disposed on the semiconductor support. The laser structure includes a semiconductor mesa and a buried region, the semiconductor mesa having a core layer, and the buried region embedding the semiconductor mesa. The laser structure includes a first region, a second region, and a third region. The third region is provided between the first region and the second region. The first region includes the first end face. The semiconductor mesa includes a first stripe portion, a second stripe portion, and a first tapered portion in the first region, the second region, and the third region, respectively. The first stripe portion and the second stripe portion have different mesa widths.

According to the quantum cascade laser, the first stripe portion and the second stripe portion has a respective mesa width. Providing a first stripe portion and a second stripe portion of each semiconductor mesa in the first region and the second region of the laser structure, the first stripe portion extends to the first end face in order to separate the tapered portion from the first end face.

The first end face of the quantum cascade laser is fabricated by cleavage from the substrate product resulting from the fabrication of the quantum cascade laser. The side surface of the semiconductor mesa bend at the joint between the tapered shape and the striped shape. According to the arrangement of the first stripe portion and the first tapered portion, the first end face is spaced apart from the joint between the stripe shape and the taper shape and from the first tapered portion. This separation, even when the cleavage surface is displaced from the desired cleavage line, it is possible to avoid the seam and the first tapered portion appears on the first end face.

The tapered shape serves, relative to the second stripe portion, as a converter for converting a spot size of a guiding light propagating through the semiconductor mesa, and is also separated from the first end face by the first stripe portion. The first stripe portion may have a mesa width smaller than the mesa width of the second stripe portion.

In the quantum cascade laser according to a specific example, the semiconductor mesa includes a semiconductor layer having a grating structure in the second region.

According to the quantum cascade laser, the grating structure of the stripe of the second stripe portion of the second region defines the oscillation wavelength of the quantum cascade laser.

In the quantum cascade laser according to a specific example, the grating structure has a termination away from the first end face.

According to the quantum cascade laser, it is possible to reduce the feedback from the grating structure in the semiconductor mesa narrower than the mesa width of the second stripe portion.

The quantum cascade laser according to a specific example further comprises an electrode provided on the laser structure, and the electrode is connected to the semiconductor mesa of the second region.

According to the quantum cascade laser, the semiconductor mesa receives carriers from the electrodes.

In a quantum cascade laser according to an embodiment, the electrode has a first edge and a second edge opposite the first edge, the first edge and the second edge of the electrode are arranged in sequence in a direction from the first end face to the second end face, and the first edge is separated from the first end face.

According to the quantum cascade laser, the separation of the first edge of the electrode can reduce the supply of carriers to the semiconductor mesa narrower than the mesa width of the stripe portion.

In the quantum cascade laser according to a specific example, the semiconductor mesa has a second tapered portion and a third stripe portion in the third region, and the first tapered portion, the third stripe portion and the second tapered portion is arranged in order in the direction from the first end face to the second end face.

According to a quantum cascade laser, a semiconductor mesa can include a plurality of tapered portions without being limited to a single tapered portion. Also, the plurality of tapered portions are connected via additional stripe portions. The arrangement of the first tapered section, the additional stripe portion and the additional tapered portion provides new seams to the semiconductor mesa. These seams are also separated from the first end face.

In the quantum cascade laser according to a specific example, the first end face extends along the first reference plane, the semiconductor mesa and the semiconductor support is arranged along the second reference plane intersecting the first reference plane, the second reference plane is inclined at an angle greater than zero degrees and smaller than 90 degrees with the first reference plane.

According to the quantum cascade laser, the first stripe portion is inclined with respect to the first end face at an angle less than 90 degrees greater than zero degrees.

The findings of the present invention can be readily understood by consideration of the following detailed description with reference to the accompanying drawings, which are given by way of illustration and in which: Subsequently, with reference to the accompanying drawings, a quantum cascade laser, an embodiment according to a method of fabricating a quantum cascade laser will be described. Wherever possible, the same parts are denoted by the same reference numerals.

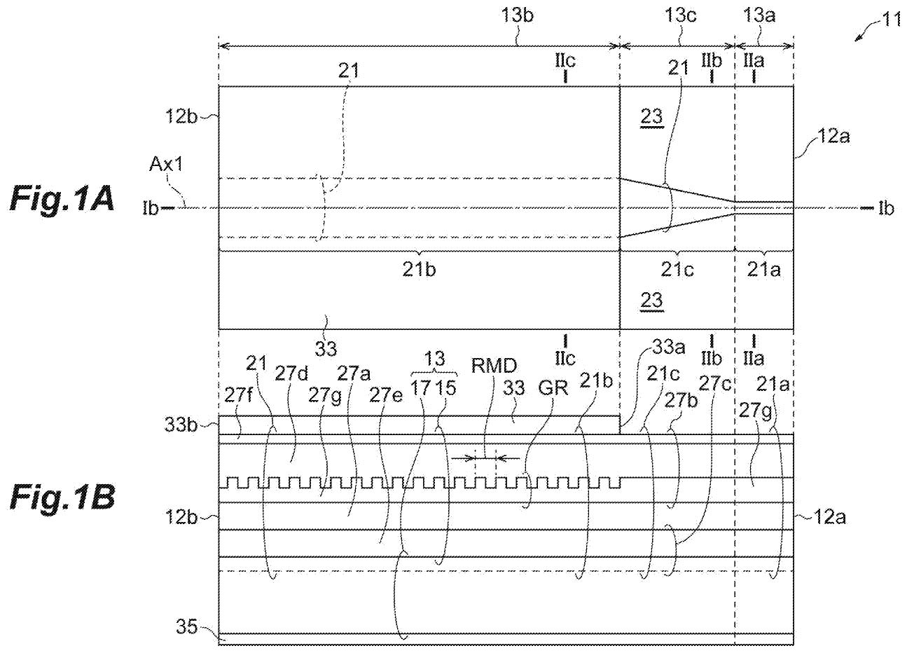

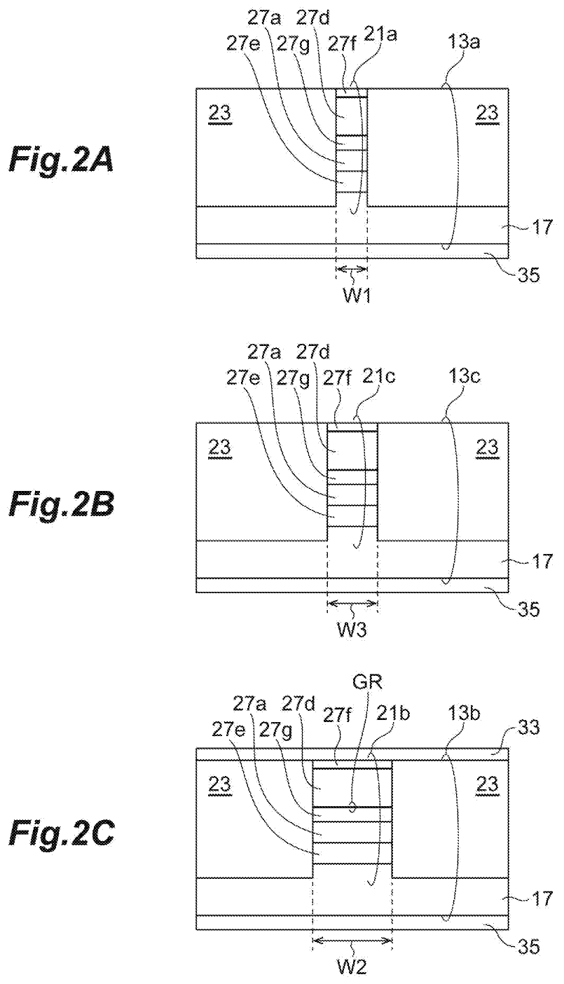

FIG. 1A is a plan view schematically showing a quantum cascade laser according to a specific example of the present embodiment. FIG. 1B shows a cross-section taken along Ib-Ib shown in FIG. 1A. FIGS. 2A, 2B and 2C are views showing cross-sections taken along IIa-IIa line, IIb-IIb line and IIc-IIc line shown in FIG. 1A, respectively.

A quantum cascade laser 11 includes a laser structure 13. The laser structure 13 has a first end face 12a and a second end face 12b. The second end face 12b is on the opposite side of the first end face 12a.

The laser structure 13 includes a first region 13a, a second region 13b, and a third region 13c, and the third region 13c is provided between the first region 13a and the second region 13b. In this embodiment, the first region 13a, the third region 13c, and the second region 13b are arranged in order in a first axial Ax1. The first region 13a includes a first end face 12a, and in this embodiment, the second region 13b may include a second end face 12b.

The laser structure 13 includes a semiconductor stack 15 and a semiconductor support 17. The semiconductor support 17 mounts the semiconductor stack 15.

The laser structure 13 includes a semiconductor mesa 21 and a buried region 23. The buried region 23 is provided on the semiconductor support 17 in the first region 13a, the second region 13b, and the third region 13c, and buries side surfaces of the semiconductor mesa 21.

In each of the first end face 12a and the second end face 12b, the buried region 23 is provided from the side surface of the semiconductor mesa 21 to the side surface of the laser structure 13.

The semiconductor mesa 21 is provided in the semiconductor stack 15 and the semiconductor support 17. Further, the semiconductor mesa 21 includes a core layer 27a that allows a quantum cascade transition, and an upper conductive semiconductor region 27b. The core layer 27a is provided between the upper conductive semiconductor region 27b and the semiconductor support 17. If necessary, the semiconductor mesa 21 may further include a lower conductive semiconductor region 27c provided on the semiconductor support 17. The core layer 27a is provided between the upper conductive semiconductor region 27b and the lower conductive semiconductor region 27c.

Specifically, the upper conductive semiconductor region 27b and the lower conductive semiconductor region 27c, respectively, may include an upper cladding layer 27d and a lower cladding layer 27e. The core layer 27a is provided between the upper cladding layer 27d and the lower cladding layer 27e.

In this embodiment, the semiconductor mesa 21 may further include a contact layer 27f. The upper conductive semiconductor region 27b includes the contact layer 27f. The lower cladding layer 27e, the core layer 27a, the upper cladding layer 27d and the contact layer 27f are arranged in order on a main surface of the semiconductor support 17 in the semiconductor mesa 21.

The semiconductor mesa 21 may further include a grating layer 27g. The upper conductive semiconductor region 27b includes the grating layer 27g. The grating layer 27g is provided between the upper cladding layer 27d and the core layer 27a in the semiconductor mesa 21, and is optically coupled to the core layer 27a. The grating layer 27g can provide a diffraction grating structure GR that allows a distributed feedback at an interface between the cladding layer (27d) and the grating layer 27g.

The semiconductor stack 15 includes the core layer 27a, the upper cladding layer 27d, the lower cladding layer 27e, the grating layer 27g, and the contact layer 27f.

The semiconductor mesa 21 includes a first stripe portion 21a, a second stripe portion 21b, and a first tapered portion 21c in the first region 13a, the second region 13b and the third region 13c, respectively. In this embodiment, the first stripe portion 21a, the first tapered portion 21c, and the second stripe portion 21b are arranged in order in the first axial Ax1. The first stripe portion 21a and the second stripe portion 21b have mesa widths different from each other. In the present embodiment, the first tapered portion 21c connects the first stripe portion 21a and the second stripe portion 21b to each other.

The first tapered portion 21c serves as a converter for converting a spot size of a guided light propagating through the second stripe portion 21b of the semiconductor mesa 21, and is separated from the first end face 12a by the first stripe portion 21a. The first stripe portion 21a may have the mesa width smaller than the mesa width of the second stripe portion 21b.

According to the quantum cascade laser 11, the first stripe portion 21a and the second stripe portion 21b are provided different mesa widths from each other. The first stripe portion 21a and the first tapered portion 21c are provided on the first region 13a and the third region 13c of the laser structure 13, respectively, and the first stripe portion 21a reaches the first end face 12a in order to separate the first tapered portion 21c from the first end face 12a.

The first end face 12a of the quantum cascade laser 11 is fabricated by breaking from a resultant product brought about by fabricating of the quantum cascade laser 11. The side surfaces of the semiconductor mesa 21 bend at a joint between a tapered shape and a striped shape. According to the arrangement of the first stripe portion 21a and the first tapered portion 21c, the first end face 12a is spaced from the first tapered portion 21c and from the joint of the tapered shape and the striped shape. This spacing allows the first end face 12a to escape from a quality degradation associated with a crystal growth that may result from the joint and the tapered shape.

The semiconductor mesa 21 has the diffraction grating structure GR in the second region 13b. According to the quantum cascade laser 11, the diffraction grating structure GR of the second stripe portion 21b in the second region 13b defines an oscillation wavelength of the quantum cascade laser 11.

The diffraction grating structure GR has a termination away from the first end face 12a. Differences in the widths of the semiconductor mesa 21 may cause differences in effective refractive indices of a waveguide including the semiconductor mesa 21. The diffraction grating structure GR may have a termination away from the first stripe portion 21a of the first region 13a. According to the quantum cascade laser 11, it is possible to avoid a distributed feedback in the first stripe portion 21a whose mesa width is narrower than the mesa width of the second stripe portion 21b.

The quantum cascade laser 11 further includes an upper electrode 33 and a lower electrode 35. The laser structure 13 is between the upper electrode 33 and the lower electrode 35.

The upper electrode 33 is provided on the laser structure 13, and is connected to the semiconductor mesa 21 in the second region 13b.

Specifically, the upper electrode 33 makes contact with an upper surface of the second stripe portion 21b of the semiconductor mesa 21 to form an interface with the semiconductor mesa 21. Carriers (e.g., electrons) flowing between the semiconductor mesa 21 and the upper electrode 33 pass through this interface.

The upper electrode 33 has a first edge 33a and a second edge 33b, the second edge 33b being opposite the first edge 33a. The first edge 33a and the second edge 33b of the upper electrode 33 are arranged in order in a direction from the first end face 12a to the second end face 12b. The first edge 33a is separated from the first end face 12a.

Specifically, the upper electrode 33 is provided on the second region 13b, and is not provided on the first region 13a nor the third region 13c. According to the quantum cascade laser 11, by the separation of the first edge 33a of the upper electrode 33, it is possible to reduce a supply of carriers to semiconductor mesas narrower than the mesa width of the second stripe portion 21b.

The lower electrode 35 is provided on a back surface of the laser structure 13, and is connected to the semiconductor mesa 21 on the first region 13a, the second region 13b and the third region 13c. Specifically, the lower electrode 35 makes contact with the semiconductor support 17 of the laser structure 13 to form an interface. Carriers (e.g., holes) flowing between the semiconductor support 17 and the lower electrode 35 passes through this interface.

One of the upper electrode 33 and the lower electrode 35, for example, the upper electrode 33 serves as a cathode electrode, the other electrode, for example, the lower electrode 35 serves as an anode electrode. An applied voltage to the quantum cascade laser 11 is, for example, on the order of 7-15 volts.

The quantum cascade laser 11 has an optical resonator. In this embodiment, the quantum cascade laser 11 has a distributed feedback optical resonator including the first end face 12a and the second end face 12b. The quantum cascade laser 11 may be provided with a reflective structure for increasing the reflectance of the second end face 12b. Such a reflective structure covers the second end face 12b and is also formed on the upper surface and lower surface of the laser structure 13 in the vicinity of the second end face 12b. Alternatively, the quantum cascade laser 11 may comprise a distributed Bragg reflector opposite the first end face 12a.

Examples of the quantum cascade lasers 11.

The upper conductive semiconductor region 27b: the upper cladding layer 27d (e.g., n-type InP) , if required, the grating layer 27g (e.g., n-type GaInAs), the contact layer 27f (e.g., n-type GaInAs).
The core layer 27a: a superlattice layer of GaInAs/AlInAs or GaInAsP/AlInAs.
The lower conductive semiconductor region 27c: the lower cladding layer 27e (e.g., n-type InP).
The semiconductor support 17: n-type InP substrate.
The buried region 23: III-V compound semiconductors such as semi-insulating or undoped InP, GaInAs, AlInAs, GaInAsP, AlGaInAs.
The upper electrode 33 and the lower electrode 35: Ti/Au, Ti/Pt/Au, or Ge/Au.
N-type dopants: silicon (Si), sulfur (S), tin (Sn), selenium (Se).

As illustrate in FIGS. 2A, 2B and 2C, the first stripe portion 21a, the second stripe portion 21b, and the first tapered portion 21c have a respective width (W1, W2, W3). The width (W1) of the first stripe portion 21a is smaller than the width (W2) of the second stripe portion 21b, and the first tapered portion 21c has the width (W3) which gradually changes so as to connect the first stripe portion 21a to the second stripe portion 21b.

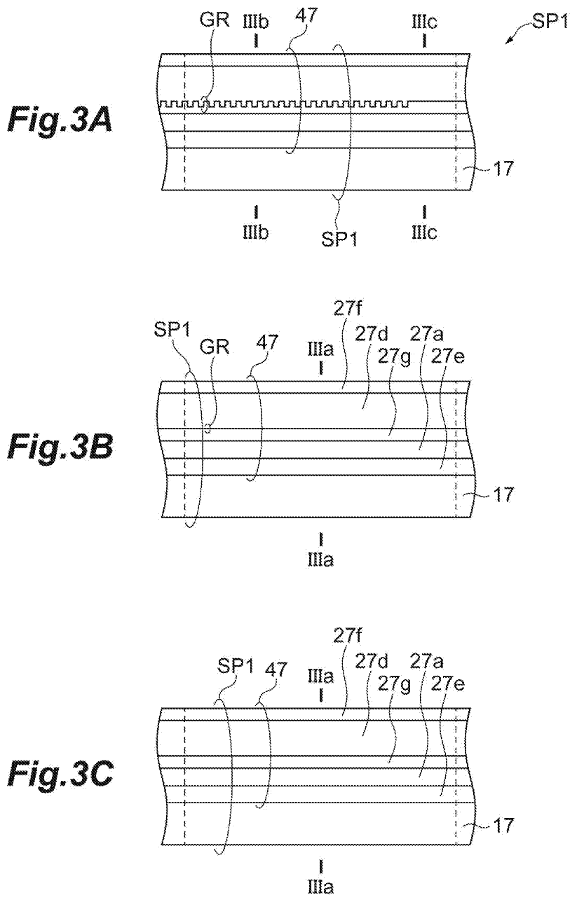

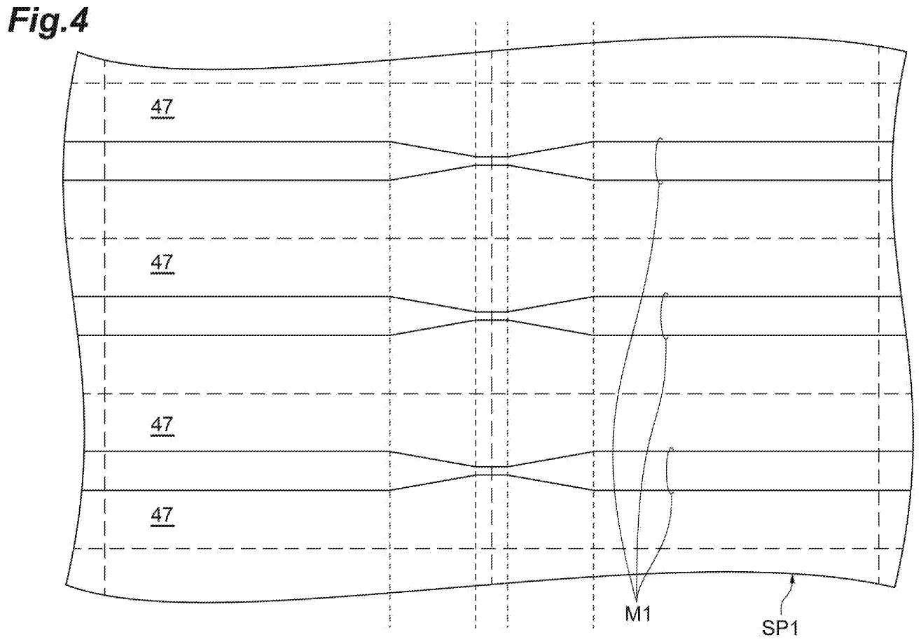

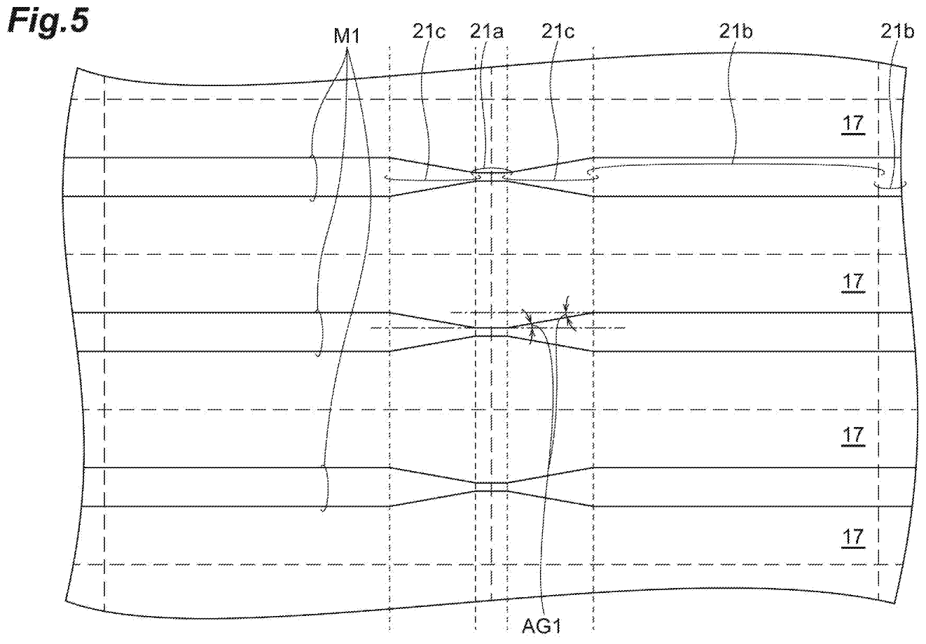

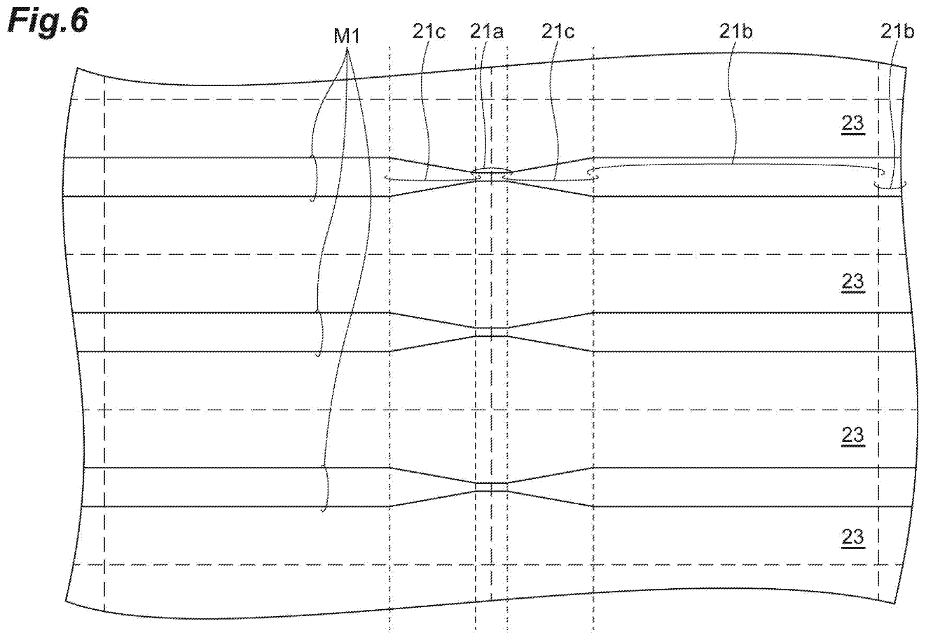

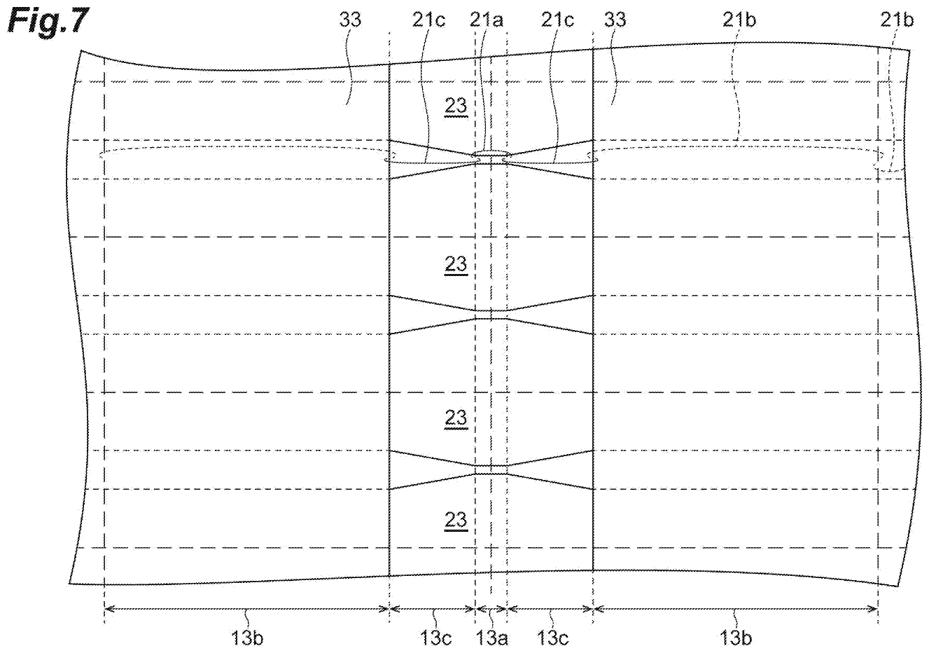

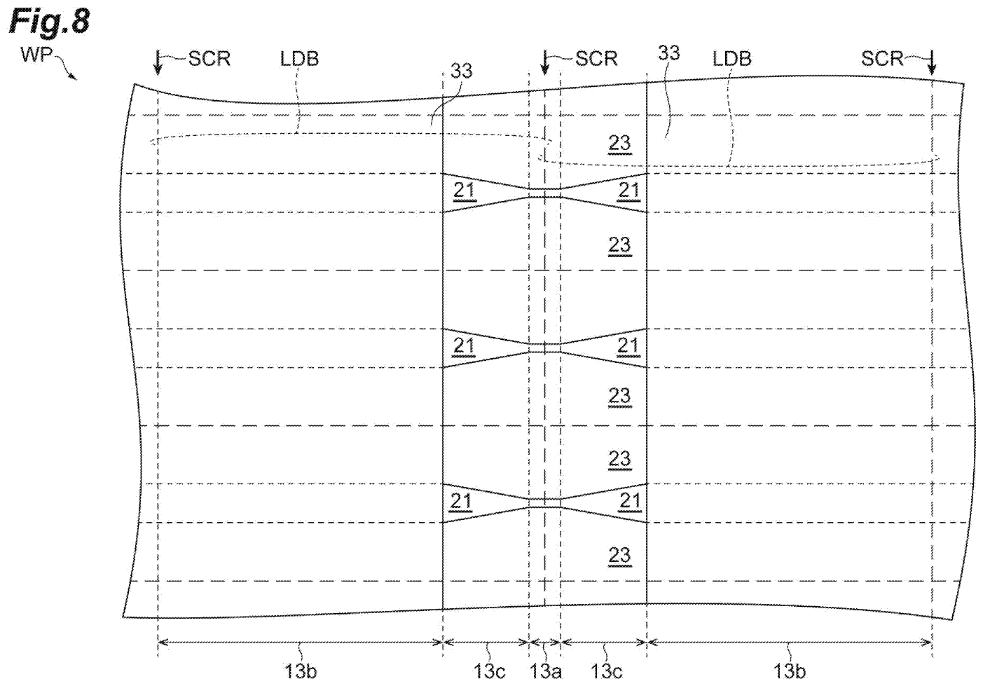

Referring to FIGS. 3A, 3B and 3C in addition to FIG. 4, FIG. 5, FIG. 6, FIG. 7, and FIG. 8, a method of fabricating the quantum cascade laser 11 will be schematically described. In the following description, reference numerals in the description made with reference to FIGS. 1A, 1B, 2A, 2B and 2C will be used where possible.

As shown in FIGS. 3A, 3B and 3C, a substrate product SP1 is prepared. FIG. 3A is a view showing a cross section taken along the first axis Ax1. FIG. 3B is a view showing a cross section along IIIb-IIIb shown in FIG. 3A. FIG. 3C is a view showing a cross section along IIIc-IIIc shown in FIG. 3A. FIG. 3A is a view showing a cross section along IIIa-IIIa shown in FIGS. 3B and 3C.

The substrate product SP1 includes a substrate for growth (referred to in the following description as the semiconductor support 17) and a stack 47 for the semiconductor stack 15. The stack 47 includes semiconductor layers for the lower cladding layer 27e of the lower conductive semiconductor region 27c, the core layer 27a, the grating layer 27g of the upper conductive semiconductor region 27b, the upper cladding layer 27d, and the contact layer 27f. Specifically, the semiconductor layers for the lower cladding layer 27e, the core layer 27a, and the diffraction grating layer 27g are grown on the semiconductor support 17, and a periodic structure for the diffraction grating structure GR is formed in the grating layer 27g by lithography and etching. On the grating layer 27g on which the diffraction grating structure GR is formed, the semiconductor layers for the upper cladding layer 27d and the contact layer 27f are grown. The semiconductor layers for semiconductor stack 15 are grown on semiconductor support 17. This growth is performed by, for example, metal-organic vapor phase deposition or molecular beam epitaxy.

The diffraction grating structure GR may be provided in the upper conductive semiconductor region 27b or the lower conductive semiconductor region 27c, and in this embodiment the diffraction grating structure GR is provided in the upper conductive semiconductor region 27b. The diffraction grating structure GR is formed at an interface between the upper cladding layer 27d and the grating layer 27g.

As shown in FIG. 4, the substrate product SP1 has an array of device segments for the quantum cascade laser 11. In the present embodiment, the array of device segments is shown as a rectangle indicated by a coarse dashed line. A mask M1 defining the semiconductor mesa 21 of the quantum cascade laser 11 is formed on the array of device segments of the substrate product SP1. Specifically, an inorganic insulating film for the mask M1 is deposited on the substrate product SP1 and the mask M1 is formed from the inorganic insulating film by photolithography and etching. The mask M1 has a pattern that extends across the array of device segments and defines a mesa shape.

As shown in FIG. 5, the stack 47 and the semiconductor support 17 are etched using the mask M1. By this etching, the semiconductor mesa 21 is formed in the individual device segments. The semiconductor mesa 21 includes a first stripe portion 21a, the first tapered portion 21c, and a second stripe portion 21b. As shown in FIGS. 1A and 1B, the first stripe portion 21a, the first tapered portion 21c, and the second stripe portion 21b are arranged in order in a direction the first axis Ax1.

In the present embodiment, the first stripe portion 21a is connected to the first tapered portion 21c, and the first tapered portion 21c is connected to the second stripe portion 21b in the device section. At a joint of the portions, a side surface of the semiconductor mesa 21 is provided with a bend relating to a tapered angle of the first tapered portion 21c (an angle AG1, ranging from 0.1 degrees to 5 degrees, for example, 0.6 degrees).

After the semiconductor mesa 21 is formed, the mask M1 is left.

As shown in FIG. 6, a semiconductor for the buried region 23 is grown on the semiconductor support 17. Specifically, a semi-insulating semiconductor is grown on the semiconductor support 17 using the mask M1 to form the buried region 23 for embedding the semiconductor mesa 21.

In the growth of the buried region, as a result of the angle AG1, a crystal growth rate for embedding the first tapered portion 21c may differ significantly from a crystal growth rate for embedding the second striped portion 21b. Further, there is a possibility that the crystal growth rate for embedding the first tapered portion 21c will be significantly different from a crystal growth rate for embedding the first stripe portion 21a, and at the joint between the first tapered portion 21c and the first stripe portion 21a, the side surface of the semiconductor mesa 21 as a result of the angle AG1 is encountered to form an angle of less than 180 degrees. At the joint, the buried region may become thicker. If a cleavage plane passes through the thickened buried region, the cleavage plane may deviate from a cleavage line.

Following completion of the growth of the buried region, the mask M1 is removed. If necessary, a protective film such as a silicon-based inorganic insulating film may be formed on an entire surface of the semiconductor support 17. The protective film has openings for electrical connections to the second stripe portion 21b.

As shown in FIG. 7, an upper electrode 33 is formed on the semiconductor mesa 21 and the buried region 23, and a lower electrode 35 is formed on the back surface of the semiconductor support 17. The upper electrode 33 makes contact with the second stripe portion 21b and the buried region 23, and the lower electrode 35 makes contact with the back surface of the semiconductor support 17.

As shown in FIG. 8, a laser bar is produced from a product WP produced by the above process. In the fabrication of the laser bar, the product WP is cleaved. Specifically, a scribe line SCR is formed on the product WP. The scribe line SCR defines a cleavage line. A laser bar LDB and a remaining product are fabricated by pressing the scribe line SCR and cleaving the product WP at that point. The remaining product is then pressed to create another laser bar LDB and further remaining products in order to create the laser bars LDB repeatedly.

While the scribe line SCR can guide a propagation of a cleavage plane, the cleavage plane may slightly deviate from the cleavage line. The first stripe portion 21a for each device section allows the deviated cleavage plane to avoid crossing the first tapered portion 21c.

In addition, the cleavage plane separating adjacent device sections passes through the first stripe portion 21a of one of the device sections. The first stripe portion 21a can separate the joint inside the device section from the cleavage plane of the cleavage (a cleavage face of the laser bar).

From above mentioned steps, the quantum cascade laser 11 is completed. The pattern of mask M1 may have an additional tapered shape in addition to a single tapered shape.

According to the inventors inspections, the cleavage plane may be shifted to both sides of the cleavage line, and an amount of the shift is in the range of 20 to 30 micrometers in absolute value with respect to the cleavage line.

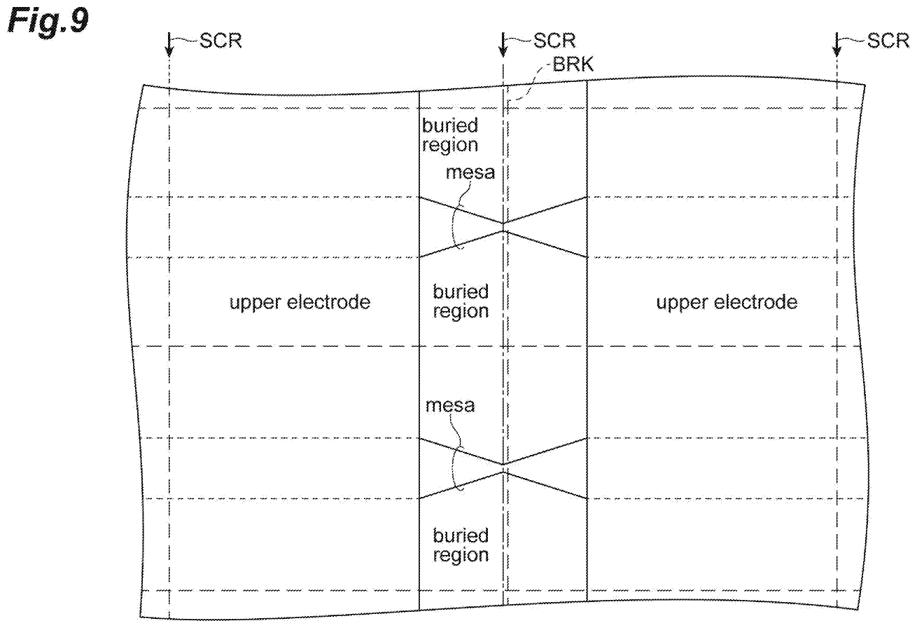

FIG. 9 schematically illustrates a cleavage step that fabricates a quantum cascade laser from a product having a structure that directly connects tapered portions in adjacent device sections. Referring to FIG. 9, there is shown a cleavage break line BRK that propagates slightly off the cleavage line (dash-dotted line) initiated from the scribe line SCR.

### EXAMPLE

A quantum cascade laser (referred to by the reference numeral “DV”) includes a semiconductor mesa that allows spot size conversion. A quantum cascade laser (referred to by the reference numeral “CV”) includes a semiconductor mesa having a single mesa width. The laser waveguide widths of the quantum cascade laser DV and the quantum cascade laser CV are 5 micrometers. The tapered portion of the semiconductor mesa of the quantum cascade laser DV has a length of 200 micrometers, a short width of 1 micrometer, and a long width of 5 micrometers.

Structures of the quantum cascade laser DV and the quantum cascade laser CV.

The semiconductor support; n-type InP substrate, plane orientation of the InP main surface (100).
Direction of extension of the semiconductor mesa: [0 −1 −1].
The upper cladding layer and the lower cladding layer: n-type InP.
The core layer: A superlattice layer of GaInAs/AlInAs.
The grating layer: n-type GaInAs.
The contact layer: n-type GaInAs.
The buried region: Fe-doped InP.
The oscillation wavelength is 7.365 micrometers.

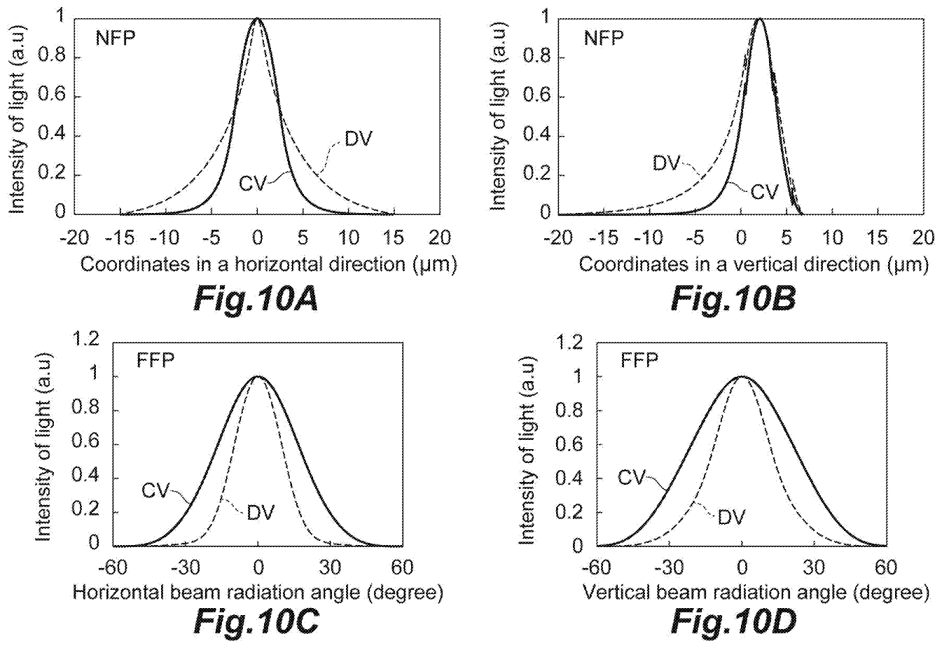

FIGS. 10A, 10B, 10C and 10D are a drawings showing near-field patterns and far-field patterns of the quantum cascade laser DV and the quantum cascade laser CV according to the example (wavelength: 7.365 micrometers).

Specifically, FIGS. 10A and 10B show the profiles of the near-field pattern (NFP) of the quantum cascade lasers. In FIG. 10A, the vertical axis represents a normalized relative intensity of light, and the horizontal axis represents the coordinates in a horizontal direction (a center of the semiconductor mesa is set to the origin, the left side from the center is designated as minus region, and the right side is designated as a positive region). In FIG. 10B, the vertical axis represents the normalized relative intensity of light, the horizontal axis represents the coordinates in a vertical direction (the main surface of the semiconductor support 17 is set to the origin, a lower side of the main surface into the semiconductor support 17 is designated as the minus region, and an upper side toward the semiconductor mesa 21 is designated as a positive region).

In the near-field pattern shown in FIG. 10A (light intensity distribution in the horizontal direction on an exit end face), the quantum cascade laser DV shows a large tailing as compared with the quantum cascade laser CV on both sides of the peak position. Further, in the near-field pattern shown in FIG. 10B (light intensity distribution in the vertical direction on the exit end face), the quantum cascade laser DV shows a large tailing as compared with the quantum cascade laser CV in the substrate.

FIGS. 10C and 10D show the profiles of the far-field pattern (FFP) of the quantum cascade lasers. In FIG. 10C, the vertical axis indicates a normalized relative intensity of the light, and the horizontal axis indicates an angle in the horizontal direction with respect to a waveguide axis. In FIG. 10D, the vertical axis indicates the normalized relative intensity of the light, the horizontal axis indicates the angle in the vertical direction with respect to the waveguide axis.

In the far-field pattern shown in FIG. 10C (horizontal light intensity distribution at a point sufficiently far from the exit end face), the quantum cascade laser CV shows a large tailing as compared with the quantum cascade laser DV on both sides of the peak position. Further, in the far-field pattern shown in FIG. 10D (vertical light intensity distribution at a point sufficiently away from the exit end face), the quantum cascade laser CV shows a large tailing compared to the quantum cascade laser DV both in the semiconductor mesa and in the substrate.

Specific values of the full width at half maximum (FWHM) in the far-field pattern are shown below.

Quantum cascade laser CV.

Horizontal beam radiation angle: 38 degrees.
Vertical beam radiation angle: 49 degrees.
Quantum cascade laser DV.
Horizontal beam radiation angle: 22 degrees.
Vertical beam radiation angle: 26 degrees.

In the quantum cascade laser DV, both horizontal and vertical beam radiation angles are reduced.

Such reduction of the beam radiation angles is provided by the quantum cascade laser DV having the first tapered portion 21c spaced from the first end face 12a by the first stripe portion 21a. In the quantum cascade laser without the first stripe portion, the first tapered portion whose width varies along the waveguide axis appears on the first end face. Therefore, owing to the deviation of the cleavage plane, the far-field pattern and the near-field pattern are not preferable, since they get closer to the far-field pattern and the near-field pattern of the quantum cascade laser CV.

The inventors' findings from the above discussion and further discussion are as follows: the first tapered portion 21c can be separated from the first end face 12a by a length of, for example, 10 micrometers or more. The first tapered portion 21c may be separated from the first end face 12a by a length of, for example, 100 micrometers or less.

The second stripe portion 21b may be separated from the first end face 12a by a length in a range of, for example, 110 to 1100 micrometers. The first tapered portion 21c may have a length in the range of 100 to 1000 micrometers. The first stripe portion 21a may have a mesa width of 0.5 to 3 micrometers, and the second stripe portion 21b may have a mesa width of 3 to 10 micrometers.

Semiconductors in the quantum cascade laser 11 will be specifically described.

The semiconductor support 17 has good conductivity and may include, for example, an n-type InP substrate. The use of InP substrates facilitates crystal growth of semiconductor layers for quantum cascade lasers with mid-infrared emission (oscillation wavelength: 3-20 micrometers).

Each of the upper cladding layer 27d and the lower cladding layer 27e may include n-type InP.

The core layer 27a includes a lamination of a unit structure composed of an active region and an injection region laminated, for example, several tens of cycles. In this lamination, a plurality of active regions and a plurality of injection regions are alternately arranged. The active and injection regions together have a superlattice array including a thin quantum well layer with a few nanometers thick and a thin barrier layer with a few nanometers thick. For example, the quantum-well layers of GaInAs or GaInAsP, as well as the barrier layers of AlInAs, allow mid-infrared oscillations.

The quantum cascade laser 11 may have a Fabry-Perot type or a distributed feedback type. The diffraction grating structure has a period RMD as shown in FIG. 1B. The period RMD specifies the Bragg wavelength. The grating layer 27g provides a distributed feedback structure to the quantum cascade laser to allow for good single-mode oscillation. Applying a semiconductor with a high refractive index, e.g., GaInAs, to the grating layer 27g can provide a large coupling coefficient to the quantum cascaded laser 11. The grating layer 27g may include, for example, an n-type or undoped semiconductor.

In this embodiment, the contact layer 27f is provided between the upper electrode 33 and the upper cladding layer 27d of the upper conductive semiconductor region 27b. The contact layer 27f may be, for example, GaInAs to provide a good ohmic contact to the quantum-cascade laser 11.

The buried region 23 may include undoped or semi-insulating semiconductors. A typical dopant for semi-insulating semiconductors is iron (Fe). The undoped semiconductors and semi-insulating host semiconductors include III-V compound semiconductors such as InP.

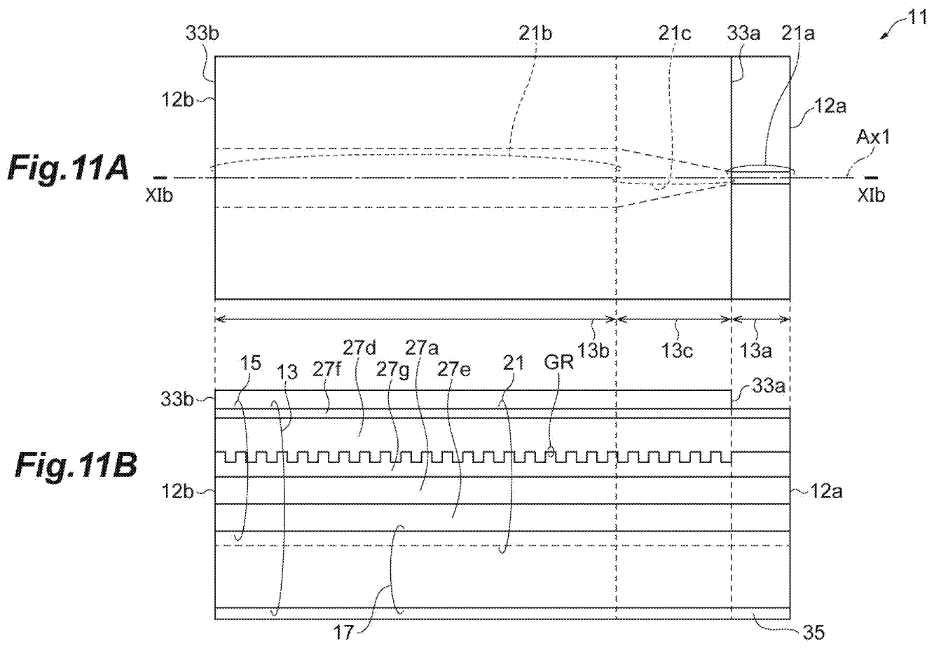

FIG. 11A is a plan view schematically showing a quantum cascade laser according to a specific example of the present embodiment. FIG. 11B is a cross-sectional view taken along XIb-XIb shown in FIG. 11A.

The diffraction grating structure GR has a termination away from the first end face 12a. Referring to FIG. 11B, the diffraction grating structure GR is provided in the second region 13b and the third region 13c, not included in the first region 13a.

The first edge 33a of the upper electrode 33 is separated from the first end face 12a. The upper electrode 33 is provided on the second region 13b and the third region 13c, and is not provided on the first region 13a.

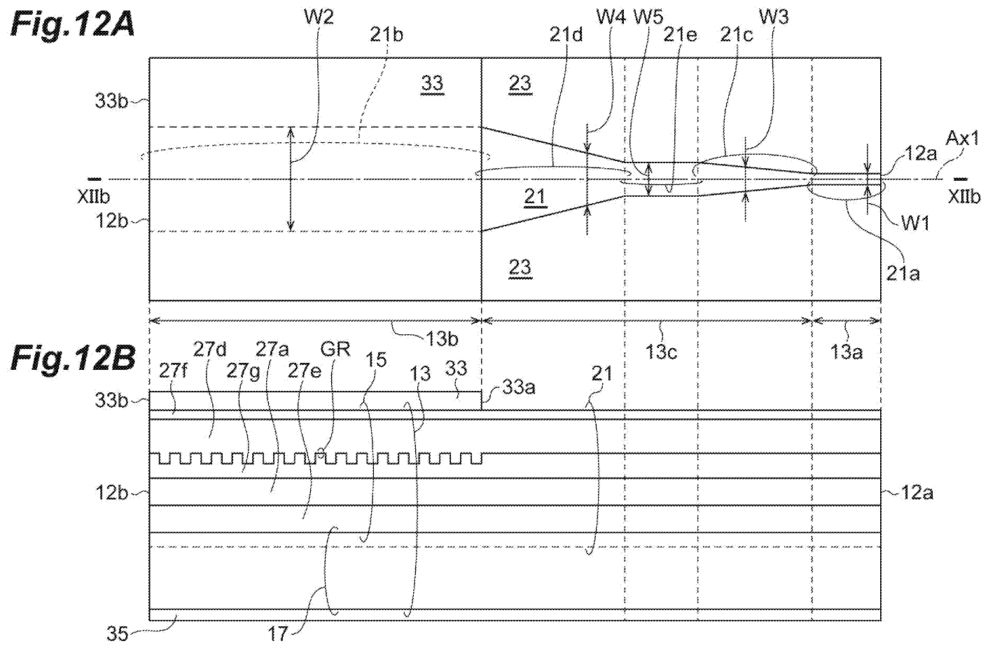

FIG. 12A is a plan view schematically showing a quantum cascade laser according to a specific example of the present embodiment. FIG. 12B is a view showing a cross section taken along XIIb-XIIb line shown in FIG. 12A.

Specifically, the semiconductor mesa 21 may have a second tapered portion 21d and a third stripe portion 21e in the third region 13c.

The first tapered portion 21c, the third stripe portion 21e and the second tapered portion 21d are arranged in a direction from the first end face 12a to the second end face 12b, for example, in the direction along the first axis Ax1.

According to the quantum cascade laser 11, the semiconductor mesa 21 may include a plurality of tapered portions without being limited to a single tapered portion. Also, the plurality of tapered portions are connected via additional stripe portions. The arrangement of the first tapered portion 21c, the third stripe portion 21e and the second tapered portion 21d gives new joints to the semiconductor mesa. These joints are also separated from the first end face 12a.

As shown in FIGS. 12A and 12B, the first stripe portion 21a, the second stripe portion 21b, the first tapered portion 21c, the third stripe portion 21e, and the second tapered portion 21d have a respective width (W1, W2, W3, W5, W4). The width (W1) of the first stripe portion 21a is smaller than the width (W5) of the third stripe portion 21e, and the width (W5) of the third stripe portion 21e is smaller than the width (W2) of the second stripe portion 21b. The first tapered portion 21c has the width W3 that gradually changes so as to connect the third stripe portion 21e to the first stripe portion 21a. The second tapered portion 21d has the width W4 that gradually changes so as to connect the second stripe portion 21b to the third stripe portion 21e.

The diffraction grating structure GR has a termination away from the first end face 12a. Referring to FIG. 12B, the diffraction grating structure GR is provided in the second region 13b, not included in the first region 13a and the third region 13c.

If necessary, the diffraction grating structure GR may be provided in the second region 13b and the third region 13c, and may not be included in the first region 13a.

If necessary, the upper electrode 33 may be provided on the second region 13b and the third region 13c, and may not be provided on the first region 13a.

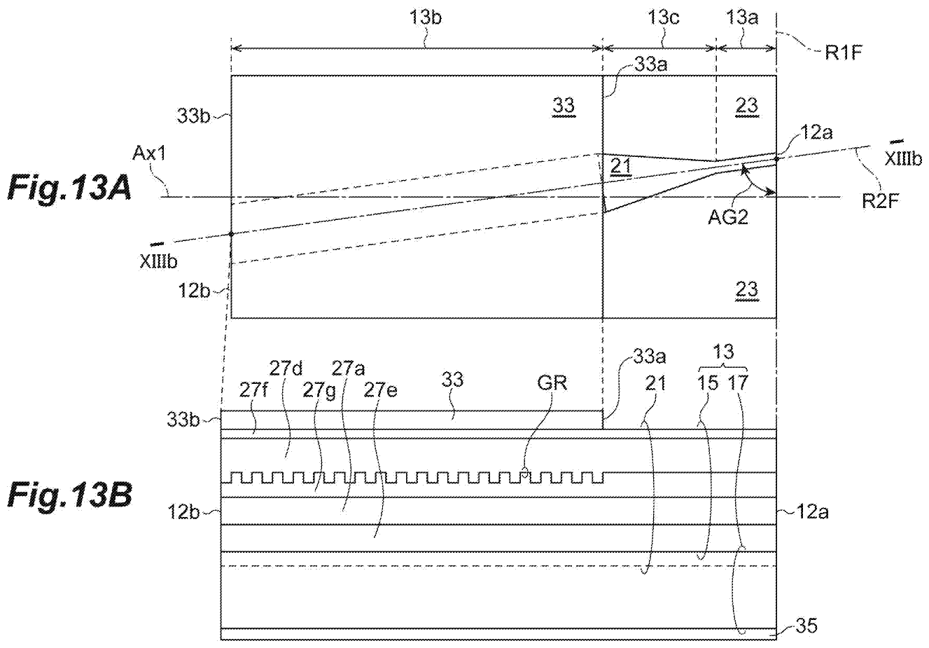

FIG. 13A is a plan view schematically showing a quantum cascade laser according to a specific example of the present embodiment. FIG. 13B is a cross-sectional view taken along XIIIb-XIIIb line shown in FIG. 13A.

The first end face 12a extends along a first reference plane R1F. The semiconductor mesa 21 and the semiconductor support 17 are arranged along a second reference plane R2F that intersects with the first reference plane R1F. As shown in FIG. 13A, the second reference plane R2F is inclined at an angle AG2 greater than zero degrees and less than 90 degrees (e.g., 80 to 85 degrees) from the first reference plane R1F.

If necessary, the semiconductor mesa 21 inclined as described above may include a plurality of tapered portions as shown in FIG. 12A.

The diffraction grating structure GR has a termination away from the first end face 12a. Referring to FIG. 12B, the diffraction grating structure GR is provided in the second region 13b, and not included in the first region 13a and the third region 13c.

If necessary, the diffraction grating structure GR is provided in the second area 13b and the third region 13c, and may not be included in the first region 13a.

If necessary, the upper electrode 33 may be provided on the second region 13b and the third region 13c, and may not be provided on the first region 13a.

According to the quantum cascade laser 11, a guided light propagating through the first stripe portion 21a and the second stripe portion 21b is incident on the first end face 12a at an angle smaller than 90 degrees greater than zero degrees. This angle may be in the range of 80 to 85 degrees, for example.

If necessary, the first end face 12a may extend along the first reference plane R1F, and the semiconductor mesa 21 and the semiconductor support 17 may be arranged along the second reference plane R2F, such that the second reference plane R2F is substantially orthogonal to the first reference plane R1F. According to the quantum cascade laser 11, the guided light propagating through the first stripe portion 21a and the second stripe portion 21b is incident on the first end face 12a at an angle of substantially 90 degrees.

While the principles of the present invention have been illustrated and described in preferred embodiments, it will be appreciated by those skilled in the art that the invention may be modified in arrangement and detail without departing from such principles. The present invention is not limited to the specific configurations disclosed in this embodiment. Accordingly, it is claimed that all modifications and changes come from the scope of the claims and their spirit.

What is claimed is:

1. A quantum cascade laser comprising:
a laser structure including a semiconductor stack and a semiconductor support, the laser structure having a first end face and a second end face opposite the first end face,
wherein the semiconductor stack is disposed on the semiconductor support,
the laser structure includes a semiconductor mesa and a buried region, the semiconductor mesa including a core layer, and the buried region embedding the semiconductor mesa,
the laser structure includes a first region, a second region, and a third region,
the third region is provided between the first region and the second region,
the first region includes the first end face,
the semiconductor mesa includes a first stripe portion, a second stripe portion, and a first tapered portion, respectively, in the first region, the second region, and the third region, and
the first stripe portion and the second stripe portion have different mesa widths.

2. The quantum cascade laser of claim 1, wherein the semiconductor mesa includes a semiconductor layer forming a grating structure in the second region.

3. The quantum cascade laser of claim 2, wherein the grating structure has a termination away from the first end face.

4. The quantum cascade laser of claim 1, further comprising
an electrode disposed on the laser structure, the electrode being connected to the semiconductor mesa of the second region.

5. The quantum cascade laser of claim 4, wherein
the electrode has a first edge and a second edge opposite the first edge,
the first edge and the second edge of the electrode are sequentially arranged in a direction from the first end face to the second end face, and
the first edge is spaced from the first end face.

6. The quantum cascade laser according to claim 1, wherein
the semiconductor mesa has a second tapered portion and a third stripe portion in the third region, and
the first tapered portion, the third stripe portion, and the second tapered portion are arranged in order in a direction from the first end face to the second end face.

7. The quantum cascade laser of claim 1, wherein
the first end face extends along a first reference plane,
the semiconductor mesa and the semiconductor support are arranged along a second reference plane intersecting the first reference plane, and
the second reference plane is inclined at an angle greater than zero degrees and less than 90 degrees with the first reference plane.
